(19) United States
(12) Patent Application Publication
(10) Pub. No.: US 2005/0104204 A1
(43) Pub. Date: May 19, 2005

(54) Wafer-level package and its manufacturing method

(76) Inventors: Takashi Kawakubo, Kanagawa-ken (JP); Takaaki Yasumoto, Kanagawa-ken (JP); Kazuhiko Itaya, Kazuhiko-ken (JP)

Correspondence Address: Finnegan, Henderson, Farabow,;Garrett & Dunner, L.L.P., 1300 I Street, N.W., Washington, DC, 20005-3315, US

(21) Appl. No.: 10/951,868

(22) Filed: Sep. 29, 2004

(30) Foreign Application Priority Data
Sep. 30, 2003 (JP) 2003-341982

(51) Int. Cl. H01L 23/34; H01L 21/48

(52) U.S. Cl. 257/724; 438/107

(57) ABSTRACT

A wafer-level package comprises: a first substrate; an electric element provided on the first substrate; a second substrate; an internal electrode pad; a well; and an external electrode pad. The second substrate is opposed to the first substrate with a predetermined gap therebetween. The electric element is provided between the first and second substrates. The internal electrode pad extends onto a first surface of one of the first and the second substrates. The inner electrode pad is connected to the electric element. The well penetrates the one of the first and the second substrates to the internal electrode. The external electrode pad is provided on a second surface of the one of the first and the second substrates and extends onto an inner wall of the well and being connected with the internal electrode pad.

### CROSS-REFERENCE TO RELATED APPLICATIONS

This application is based upon and claims the benefit of priority from the prior Japanese Patent Application No. 2003-341982, filed on Sep. 30, 2003; the entire contents of which are incorporated herein by reference.

### BACKGROUND OF THE INVENTION

The present invention relates to a wafer-level package and its manufacturing method. More specifically, the invention relates to a wafer-level package which has a cavity inside the package and is suitable for a high frequency circuit or an analog circuit having small number of connecting pins, and its manufacturing method.

Recently, a package has been highly desired to be small sized, thin and inexpensive. Particularly, in high frequency circuit, such a package has been needed for a small-sized mobile equipment in accordance with upgrading and diversifying of the wireless communication systems. For this reason, a wafer-level package is paid an attention, as an ultimate package, in which a thin film device is formed on a substrate wafer, the wafer is also used as a packaging member itself and the wafers can be assembled entirely.

One of the major problems of the wafer-level package is how to connect internal bonding pads on a substrate surface to external electrode pads on an outer surface of the package.

To solve the above problem, several methods are known. In the first method, external electrode pads through insulating layers are provided on peripheral areas of the substrate connected to internal connection pads by wires and the connecting portion is buried with resin. This method is disclosed in Japanese Patent Laid Open Publication No. 2002-9195 and Japanese Patent Laid Open Publication No. 2002-110855.

In the second method, after a via hole is formed on the surface side of the substrate, a conductive material is buried in the via hole. Subsequently, the backside of the substrate is lapped, the conductive material in the via hole is exposed and an external electrode pad is formed on the backside of the substrate. This method is disclosed in Japanese Patent Laid Open Publication No. 2001-68616.

In the third method, a cap wafer is fixed with a predetermined spacing on the substrate and the bonding pad on the substrate is connected via through hole provided on the cap wafer by bonding wire. This method is disclosed in Japanese Patent Laid Open Publication No. 2001-68580.

However, by the above-mentioned first and third methods, when a frequency becomes over gigahertz-band, the problem that parasitic inductance degrades a band characteristics arise in a high frequency circuit. Thus, it is desirable that the wire-bonding is not used.

By the second method, the trade-off between the formation of the via hole and embedment of the via metal becomes the problem. That is, in the case of the via hole of 100 micrometers depth which is equivalent to the substrate thickness after lapping, if the via hole has as large diameter as tens of micrometers, the etching becomes easy. On the other hand, if the via hole has several micrometers diameter and large aspect ratio, complicated process for forming the via hole is needed, such as repeating etching and forming protective layer of sidewalls of the via hole.

Further, in the case of embedding a conductive layer (a part of which may be an insulator) in the via hole, if the via hole has a large diameter of tens of micrometers, a long processing time is needed, such as embedding the precise conductive layer of tens of micrometers thickness by a process for thin film including in thin film the conductive layer sputtering, CVD, and plating. On the other hand, if the via hole has several micrometers diameter, the via hole is relatively easy to be embedded in. Additionally, if the via hole has large diameter, a problem also occurs that an integration density of the via hole falls.

Thus, the method of connecting internal bonding pads to external bonding pads has a problem that the via hole of small diameter is hard to be etched and the via hole of large diameter is hard to be embedded in.

### SUMMARY OF THE INVENTION

According to an embodiment of the invention, there is provided a wafer-level package comprising:
a first substrate;
an electric element provided on the first substrate;
a second substrate opposed to the first substrate with a predetermined gap therebetween, the electric element being provided between the first and second substrates;
an internal electrode pad extending onto a first surface of one or both of the first and the second substrates, the internal electrode pad being connected to the electric element;
a well penetrating the one of the first and the second substrates to the internal electrode; and
an external electrode pad provided on a second surface of the one of the first and the second substrates, the external electrode pad extending onto an inner wall of the well and being connected with the internal electrode pad.

According to another embodiment of the invention, there is provided a method for manufacturing a wafer-level package comprising:
forming an electric element and an internal electrode pad connected to the electric element on a first surface of a first substrate;
bonding a second substrate to the first substrate by a bonding member so that the electric element and the internal electrode pad are placed between the first and second substrates;
forming a well extending from a second surface of the first substrate to the internal electrode pad;
forming an external electrode pad extending from the second surface of the first substrate to the internal electrode pad through an inner wall of the well.

According to another embodiment of the invention, there is provided a method for manufacturing a wafer-level package comprising:
forming an electrical element on a first surface of a first substrate;
forming an internal electrode pad on a first surface of a second substrate;
arranging the first and the second substrates face to face so that the electric element on the first substrate is connected to the internal electrode on the second substrate by a bump;
forming a well extending from a second surface of the second substrate to the internal electrode pad; and
forming an external electrode pad extending from the second surface of the second substrate to the internal electrode pad through an inner wall of the well.

### BRIEF DESCRIPTION OF THE DRAWINGS

The present invention will be understood more fully from the detailed description given herebelow and from the accompanying drawings of the embodiments of the invention. However, the drawings are not intended to imply limitation of the invention to a specific embodiment, but are for explanation and understanding only.

In the drawings:

FIG. 1 is a schematic diagram illustrating the cross-sectional structure of the wafer-level package according to the embodiment of the invention;

FIG. 2 is an enlarged cross-sectional view of the well;

FIG. 3 shows process step for manufacturing the wafer-level package according to the first example of the invention;

FIG. 4 shows process step for manufacturing the wafer-level package according to the first example of the invention;

FIG. 5 shows process step for manufacturing the wafer-level package according to the first example of the invention;

FIG. 6 shows process step for manufacturing the wafer-level package according to the first example of the invention;

FIG. 7 shows process step for manufacturing the wafer-level package according to the first example of the invention;

FIG. 8 shows process step for manufacturing the wafer-level package according to the first example of the invention;

FIG. 9 shows process step for manufacturing the wafer-level package according to the first example of the invention;

FIG. 10 shows process step for manufacturing the wafer-level package according to the first example of the invention;

FIG. 11 shows process step for manufacturing the wafer-level package according to the second example of the invention;

FIG. 12 shows process step for manufacturing the wafer-level package according to the second example of the invention;

FIG. 13 shows process step for manufacturing the wafer-level package according to the second example of the invention;

FIG. 14 shows process step for manufacturing the wafer-level package according to the third example of the invention;

FIG. 15 shows process step for manufacturing the wafer-level package according to the third example of the invention;

FIG. 16 shows process step for manufacturing the wafer-level package according to the third example of the invention;

FIG. 17 shows process step for manufacturing the wafer-level package according to the third example of the invention;

FIG. 18 shows process step for manufacturing the wafer-level package according to the third example of the invention;

FIG. 19 shows process step for manufacturing the wafer-level package according to the third example of the invention;

FIG. 20 shows process step for manufacturing the wafer-level package according to the third example of the invention;

FIG. 21 shows process step for manufacturing the wafer-level package according to the third example of the invention;

FIG. 22 shows process step for manufacturing the wafer-level package according to the fourth example of the invention;

FIG. 23 shows process step for manufacturing the wafer-level package according to the fourth example of the invention;

FIG. 24 shows process step for manufacturing the wafer-level package according to the fourth example of the invention;

FIG. 25 shows process step for manufacturing the wafer-level package according to the fourth example of the invention;

FIG. 26 shows process step for manufacturing the wafer-level package according to the fourth example of the invention;

FIG. 27 shows process step for manufacturing the wafer-level package according to the fourth example of the invention;

FIG. 28 shows process step for manufacturing the wafer-level package according to the fourth example of the invention;

FIG. 29 shows process step for manufacturing the wafer-level package according to the fourth example of the invention;

FIG. 30 shows process step for manufacturing the wafer-level package according to the fifth example of the invention;

FIG. 31 shows process step for manufacturing the wafer-level package according to the fifth example of the invention;

FIG. 32 shows process step for manufacturing the wafer-level package according to the fifth example of the invention;

FIG. 33 shows process step for manufacturing the wafer-level package according to the fifth example of the invention;

FIG. 34 shows process step for manufacturing the wafer-level package according to the fifth example of the invention;

FIG. 35 shows process step for manufacturing the wafer-level package according to the fifth example of the invention;

FIG. 36 shows process step for manufacturing the wafer-level package according to the fifth example of the invention;

FIG. 37 shows process step for manufacturing the wafer-level package according to the fifth example of the invention;

FIG. 38 shows process step for manufacturing the wafer-level package according to the sixth example of the invention;

FIG. 39 shows process step for manufacturing the wafer-level package according to the sixth example of the invention;

FIG. 40 shows process step for manufacturing the wafer-level package according to the sixth example of the invention;

FIG. 41 shows process step for manufacturing the wafer-level package according to the sixth example of the invention; and

FIG. 42 shows process step for manufacturing the wafer-level package according to the sixth example of the invention.

### DETAILED DESCRIPTION

Referring to drawings, some embodiments of the present invention will now be described in detail.

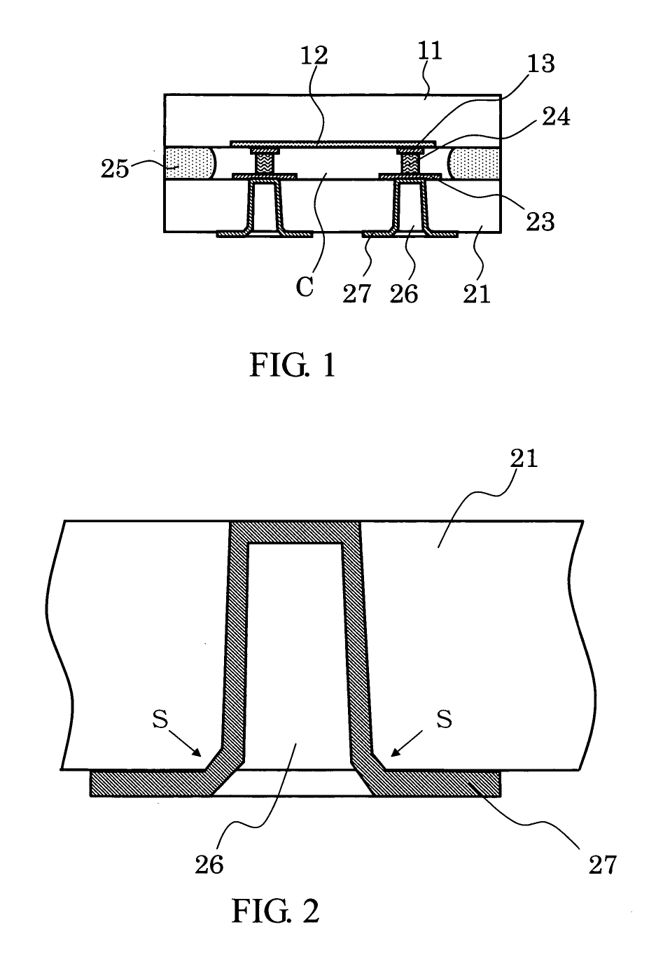

FIG. 1 is a schematic diagram illustrating the cross-sectional structure of the wafer-level package according to the embodiment of the invention. The wafer level package of this embodiment has a structure in which a first substrate 11 and a second substrate 21 are facing each other and disposed with appropriate gap by adhesive resin 25. That is, a cavity C is formed between these substrates 11 and 21. A semiconductor device 12 is provided in a manner exposed to the cavity C or covered with the protective film etc. The semiconductor device 12 may be a device having various kinds of structures and functions, such as a transistor, a diode, a resistive element, an inductor, and a capacitor, a MEMS(Micro-Electro-Mechanical System) switch, a MEMS variable capacitor, and a FBAR(thin Film Bulk Acoustic wave Resonator) for example.

The leads from the semiconductor device 12 are connected to the outside of the package through the external electrode pads 27. That is, in the structure illustrated in this figure, the leads are connected between the semiconductor device 12 and the external electrode pads 27 through first internal electrode pads 13, and stud bumps 24 and second internal electrode pads 23. The external electrode pads 27 can be formed by depositing a conductive material in the well and on the underside of well 26 penetrating the substrate 21 and on the back of the substrate 21. And the external electrode pads 27 extending to the back of the substrate 21 can be connected to external circuits, such as an assembly board (not shown), by surface mounting on a substrate electrode or wire bonding.

One of the features of wafer-level package of this embodiment is that the “chamfered edges” are provided at the opening of the well 26 penetrating the substrate 21.

FIG. 2 is an enlarged cross-sectional view of the well. As illustrated in this figure, at the entry, the chamfered edges S are formed. The chamfered edges S are formed by inclining or rounding the corners of the opening. By providing such chamfered edges S, the “stepped cut” of the external electrode pads 27 covering the chamfered edges at the opening of the well can be suppressed. Consequently, the wires can be connected surely to the back side of the substrate 21 from the semiconductor device 12, and can be connected with the external circuit which is not shown.

Further, in this embodiment, the well 26 may be formed in a taper shape that the inside diameter becomes small gradually as it approaches to the substrate 11, instead of perpendicular through hole. If the well 26 are formed in a taper shape, the external electrode pads 27 can be surely deposited to have sufficient thicknesses also on the walls of the well 26 by such method as a sputtering and vapor deposition, for example. Consequently, the “stepped cut” of the external electrode pads 27 on the walls of the well 26 can be prevented.

The chamfered edge S and the well 26 in a taper shape explained above can be easily formed by the manufacturing method according to the embodiment. That is, in the invention, as explained in full detail later, after facing the first substrate 11 and the second substrate 21 each other, the well 26 are formed by etching the second substrate 21 from the back side of the substrate (the bottom in FIG. 1 and FIG. 2). Then, the well in a taper shape that the inside diameter becomes small as it approaches to the substrate 11 and having the chamfered edge S become easy to be formed with effects, such as the so-called “side etching” etc.

Referring to examples, the wafer-level package and its manufacturing method of this embodiment will now be described in further detail.

### FIRST EMBODIMENT

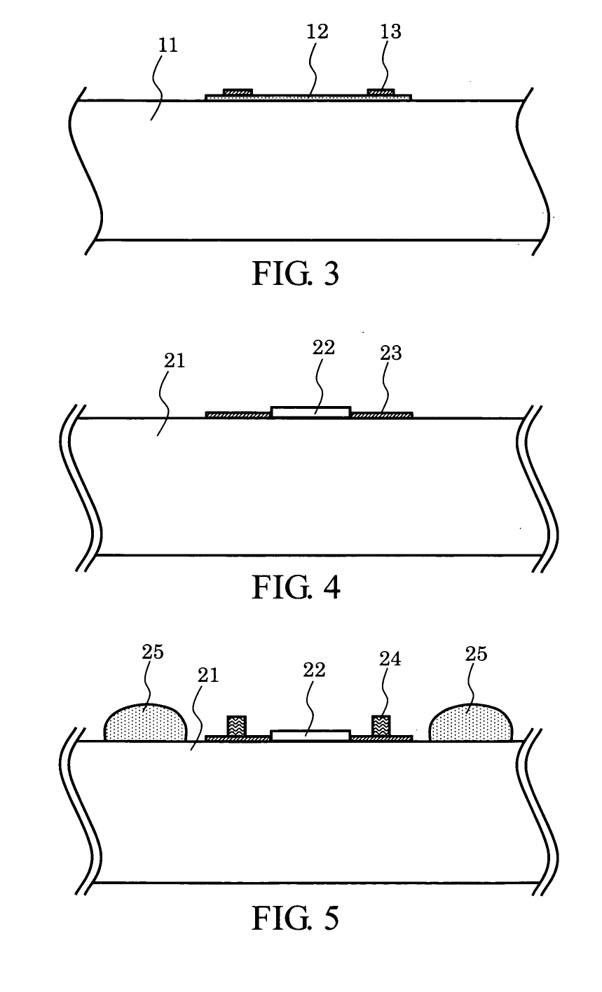

FIG. 3 through FIG. 10 show process steps for manufacturing the wafer-level package according to the first example of the invention.

In FIG. 3, the first internal electrode pads 13 of Aluminum (Al) etc. and the semiconductor device 12 are provided on the surface of the first substrate 11 of silicon (Si) by a well-known method. The first substrate 11 may be an entire wafer or a divided wafer. It is desirable that the first substrate 11 has enough area to dispose a plurality of semiconductor chips thereon.

In FIG. 4, a FBAR 22 and the second internal electrode pads 23 of Aluminum (Al) etc. are provided on the surface of the second substrate 21 of silicon (Si) prepared separately by a well-known method. The second substrate 21 may be an entire wafer or a divided wafer. The second substrate 21 is needed to have the same shape as the first substrate 11 substantially.

In FIG. 5, stud bumps 24 are formed on the second internal electrode pads 23 using bonding wires of Au. And the adhesive resin 25 is coated using a dispenser along the periphery of the thin film piezoelectric resonator 22 and the second internal electrode pads 23.

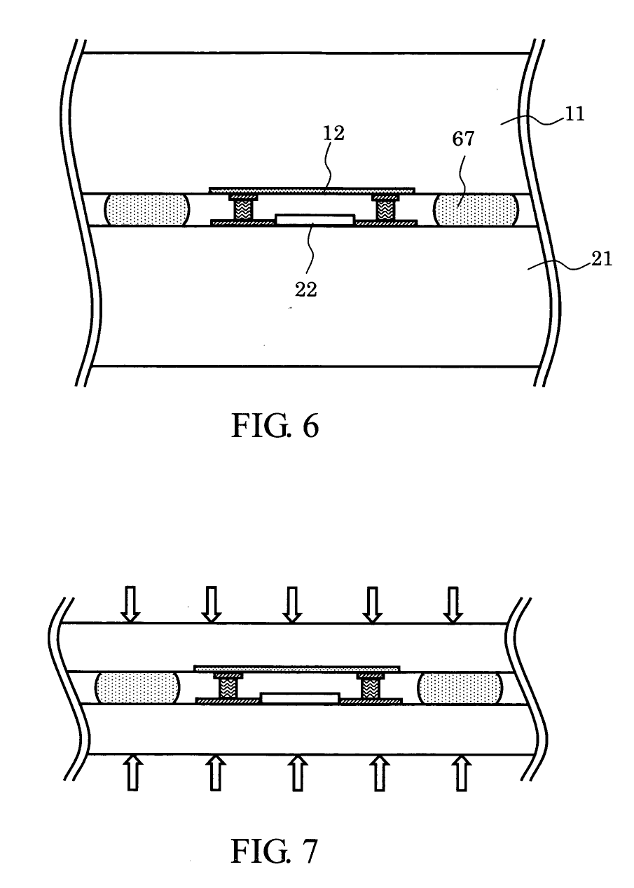

In FIG. 6, the first substrate 11 and the second substrate 21 are facing, and the stud bumps 24 and the first internal electrode pads 13 are connected electrically by an ultrasonic bonding. At the same time, the first substrate 11 and the second substrate 21 are stuck with the adhesive resins 25, and cured by heating.

In FIG. 7, the first substrate 11 and the second substrate 21 are thinned up to the thickness of 200 micrometers by grinding them on their back sides.

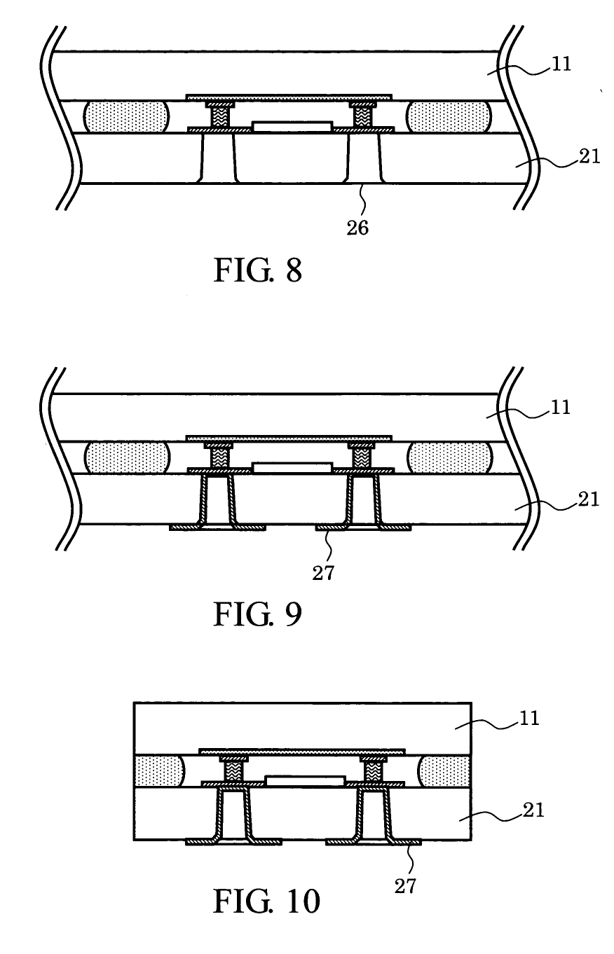

In FIG. 8, the well 26 of 200 micrometers inner diameter and depth which extends to the back sides of the second internal electrode pads 23 from the second substrate 21 are formed using a well-known photolithographic process and a reactive ion etching process. Even if a highly isotropic etching process such as a reactive ion etching is used, the chamfered edges S are formed at the corner of the opening ends of the well 26 in many cases. Moreover, it is also possible to form the chamfer parts S still more certainly by rounding the opening ends of the well 26 with a method of exposing lightly to a wet etchant, isotropic etching atmosphere, etc., after carrying out the opening of the well 26 by etching means, such as reactive ion etching.

By the highly anisotropy etching method, when opening the well 26, the well 26 whose sides are almost perpendicular to the major surface of the substrate are formed. On the other hand, by the etching method of a low anisotropy, when opening the well 26, the well 26 are formed in a taper fashion in which the inner diameter becomes small as it approach to the substrate 11 from the opening ends (bottom in the figure). Thus, it becomes possible to suppress more surely the stepped cut of the external electrode pads deposited later.

Thus, in FIG. 9, after opening the well 26, Ti adhesion layer and Au electrode layer are deposited conformally in the walls and at the bottom of the well 26 and on the backside of the second substrate 21 by sputtering, for example. And the external electrode pads 27 are patterned by lithography and dry etching. For this process, the second internal electrode pads 23 and the external electrode pads 27 can be connected electrically.

In FIG. 10, the portion stuck with adhesive resin 25 are separated for every chip by dicing.

By the above-mentioned method, the wafer-level package in which the semiconductor device 12 or the thin film piezoelectric resonator 22 are sealed in the cavity C, and their wirings are connected to the back side of the substrate 21 is obtained. Thus, it is valuable that according to this embodiment, the package for surface mount in which the wafer can be in block sealed, which has thin and small size as same as a chip, and in which the thin film device and the semiconductor device are encapsulated inside the cavity can be formed.

### SECOND EMBODIMENT

Since the process steps of the second example before the process steps mentioned above in FIG. 9 are the same as that of the first example, only the subsequent process steps will be explained.

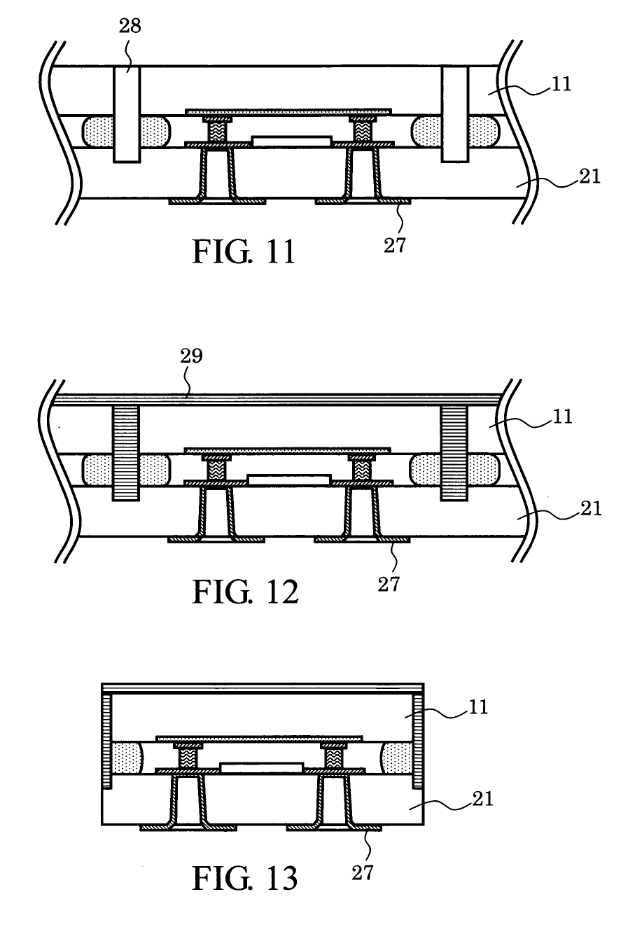

FIG. 11 through FIG. 13 show process steps for manufacturing the wafer-level package according to the second example of the invention. In FIG. 11, after the process step shown in FIG. 9, the trenches 28 are formed by half-cutting the regions stuck with sealing resin 25 using a dicing saw of 200 micrometers width to the second substrate 21 from the back side of the first substrate 11.

In FIG. 12, the backside of the first substrate 11 is covered with the adhesive resin 29 and is cured.

In FIG. 13, dicing is performed using the dicing saw of 30 micrometers width, and the central parts of the trenches 28 are separated for every chip.

By such processes, in addition to the same effect as the first example, since the sides of the package are doubly covered with the adhesive resin 25 and the sealing resin 29, environmental resistance improves further. Moreover, since the upper surface of the package is covered with the adhesive resin 29, it becomes possible to mark on the surface. Therefore, the industrial value is very large.

### THIRD EMBODIMENT

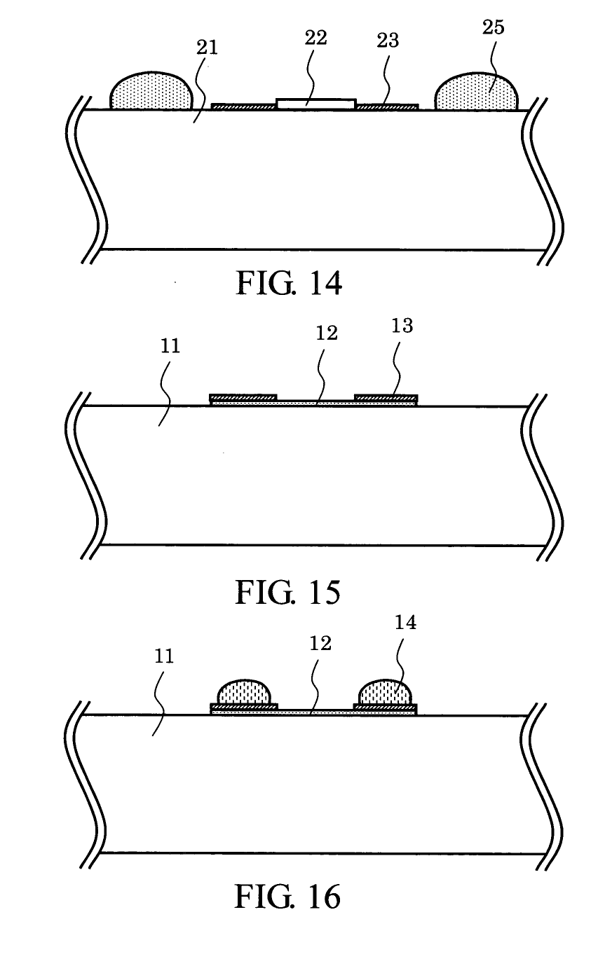

FIG. 14 through FIG. 21 are process steps for manufacturing method of the wafer-level package according to the third example of the invention.

In FIG. 14, a microswitch 22 and the second internal electrode pads 23 of aluminum are provided on the surface of the second substrate 21 of Si by a well-known method. The second substrate 21 may be an entire wafer or a divided wafer. It is desirable that the second substrate 21 is the same shape as the first substrate 11. Further, the adhesive resin 25 are printed by screen-print along the periphery of the microswitch 22 and the second internal electrode pads 23.

Moreover, in FIG. 15, the semiconductor device 12 and the first internal electrode pads 13 of aluminum are provided on the surface of the first substrate 11 of Si by a well-known method.

In FIG. 16, conductive resin 14 is printed on the first internal electrode pads 13 using screen printing.

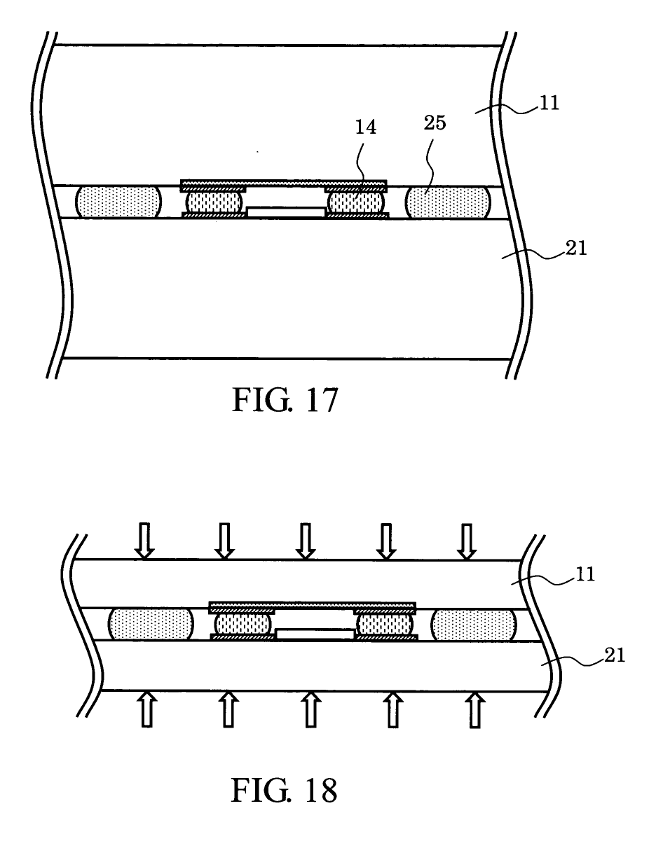

Next, as shown in FIG. 17, the first substrate 11 and the second substrate 21 are facing so that the surfaces may face each other, and the first internal electrode pads 13 and the second internal electrode pads 23 are connected by conductive resin 14. Simultaneously, the first substrate 11 and the second substrate 21 are stuck with adhesive resin 25, and are sealed by cured with heating.

In FIG. 18, the first substrate 11 and the second substrate 21 are thinned up to the thickness of 200 micrometers by grinding them on their backsides.

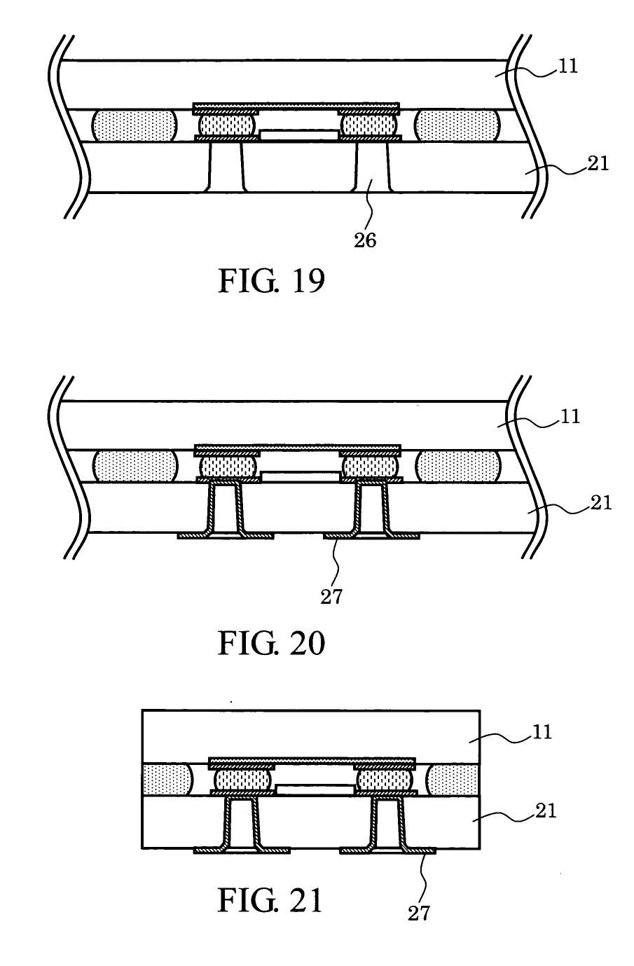

In FIG. 19, well 26 of 200 micrometers inner diameter and depth which extend to the back sides of the second internal electrode pads 23 from the second substrate 21 are formed using a well-known photolithographic process and reactive ion etching process. Then, as mentioned above about the first example, the chamfered edges S can be formed surely and easily. Further, the well 26 may be opened in a taper shape.

In FIG. 20, Ti adhesion layer and Au electrode layer are deposited conformally in the walls and at the bottom of the well 26 and on the backside of the second substrate 21 by a sputtering, for example. And the external electrode pads 27 are patterned by lithography and dry etching. For this process, the second internal electrode pads 23 and the external electrode pads 27 can be connected electrically.

In FIG. 21, the portion stuck with adhesive resin 25 are separated for every chip by dicing. Thus, it is valuable that according to this embodiment, the package for surface mount in which the wafer can be collectively encapsulated, which has thin and small size as same as a chip, and in which the thin film device and the semiconductor device are sealed inside the cavity can be formed.

In particular, according to this example, the internal electrode pads 13 and 23 can be connected electrically with the conductive resin 14. The advantage that the conductive resin 14 has high manufacturability for being easily formed by screen printing etc. can be acquired.

### FOURTH EMBODIMENT

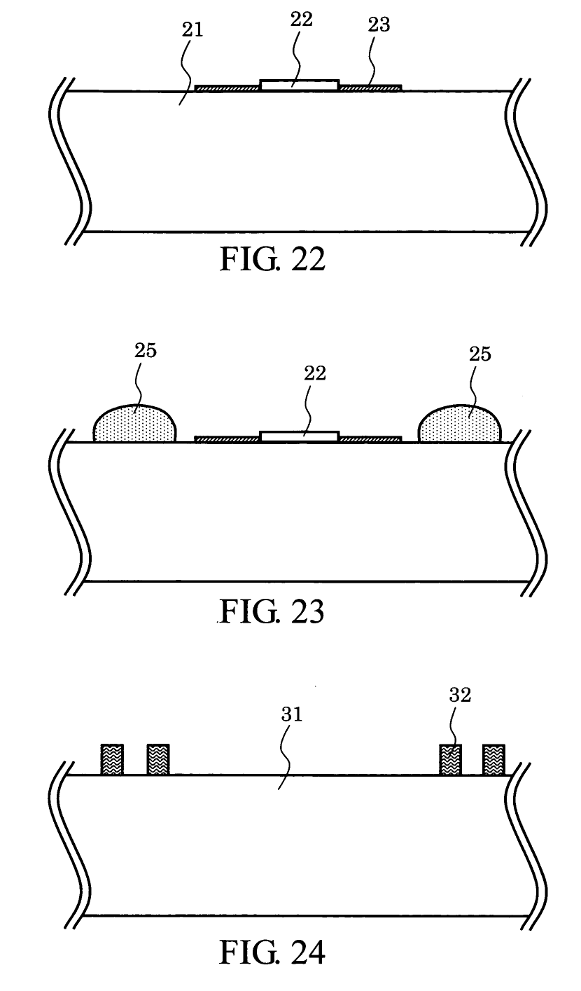

FIG. 22 through FIG. 29 show process steps for manufacturing method of the wafer-level package according to the fourth example of the invention.

In FIG. 22, the thin film piezoelectric resonator and the second internal electrode pads 23 of aluminum are provided on the surface of the first substrate 21 of glass by a well-known method.

In FIG. 23, the adhesive resin 25 is coated by an ink-jet method along the periphery of the thin film piezoelectric resonator 22 and the second internal electrode pads 23.

In FIG. 24, Si oxide film is deposited on the surface of the second substrate 31 of glass prepared separately by the plasma CVD method. Bumps 32 are patterned by photolithography and reactive ion etching.

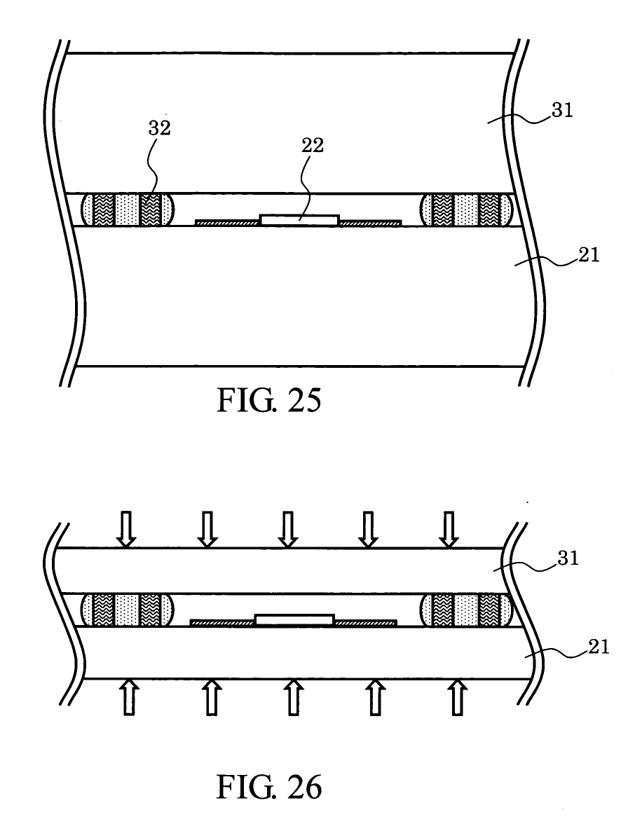

In FIG. 25, the surfaces of the first substrate 21 and the second substrate 31 are opposed using the bumps 32 as stoppers, are stuck using the adhesive resin 25, and are sealed by cured with heating.

In FIG. 26, the first substrate 21 and the second substrate 31 are thinned up to the thickness of 200 micrometers by grinding them on their backsides.

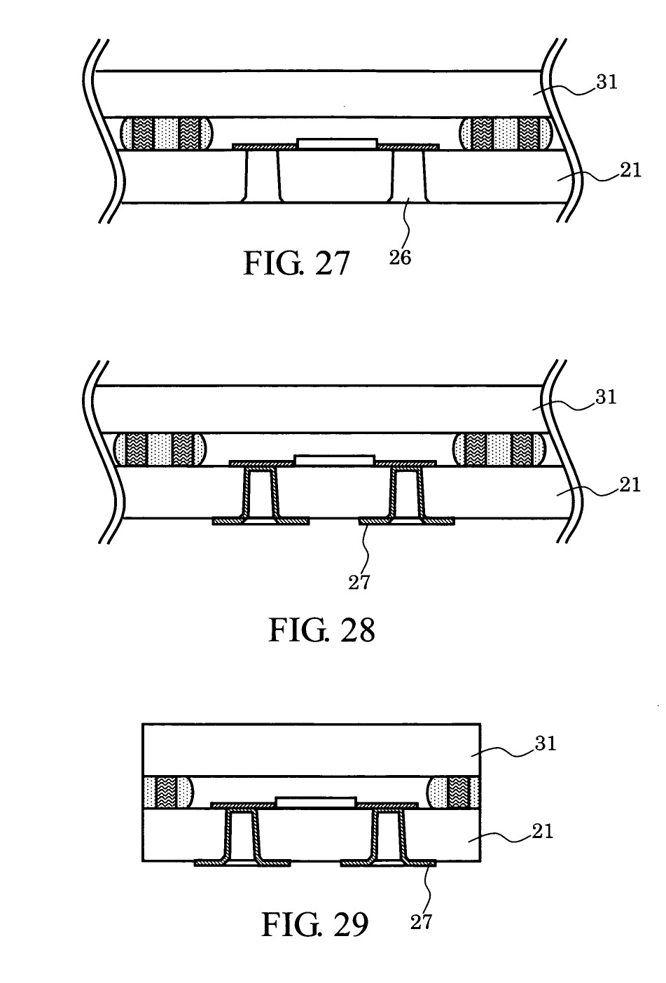

In FIG. 27, well 26 of 200 micrometers inner diameter and depth which extend to the back sides of the second internal electrode pads 23 from the second substrate 21 are formed using a well-known photolithographic process and reactive ion etching process. Then, as mentioned above about the first example, the chamfered edges S can be formed certainly and easily. Further, the well 26 maybe opened in a taper fashion. In FIG. 28, Ti adhesion layer and Au electrode layer are deposited conformally in the walls and at the bottom of the well 26 and on the backside of the second substrate 21 by methods, such as a sputtering. And the external electrode pads 27 are patterned by lithography and dry etching. For this process, the second internal electrode pads 23 and the external electrode pads 27 can be connected electrically. In FIG. 29, the portion stuck with adhesive resin 25 are separated for every chip by dicing.

According to this example, elements, such as the thin film piezoelectric resonator, can be sealed between two glass substrates, and the space of the cavity can be prescribed by the bumps 32.

### FIFTH EMBODIMENT

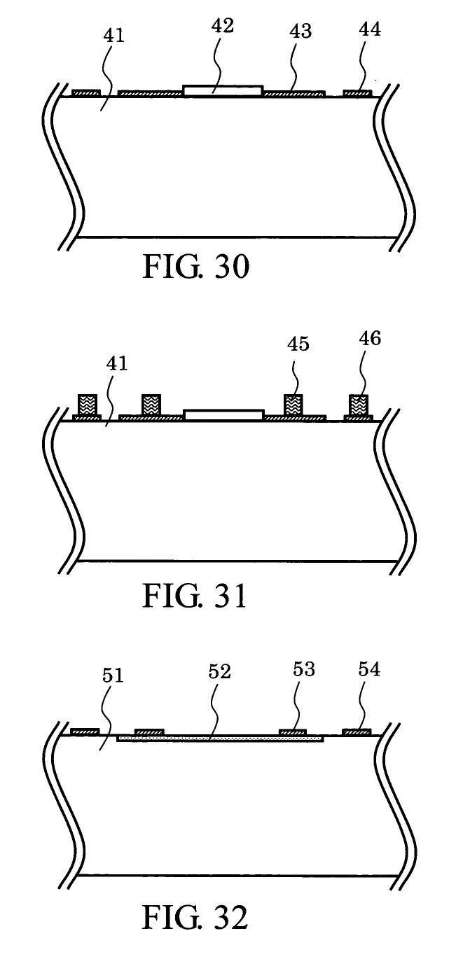

FIG. 30 through FIG. 37 are process steps for manufacturing method of the wafer-level package according to the fifth example of the invention.

In FIG. 30, a microswitch 42, the first internal electrode pads 43 of aluminum, and first sealing pads 44 encompassing the internal electrode pads are provided on the surface of the first substrate 41 by a well known method. The first substrate 41 may be an entire wafer or a divided wafer. It is desired that the first substrate 41 has enough area to dispose a plurality of thin film device chips thereon.

In FIG. 31, the bumps 45 of gold for internal connection and the bumps 46 for sealing are formed on the first internal bonding electrode pads 43 and the first sealing pads 44 by a lithography method and a selective plating method. In FIG. 32, the semiconductor device 52, the second internal electrode pads 53 of gold, and the second sealing pads 54 encompassing the internal electrode pads are formed on the surface of the second substrate 51 of Si prepared before by a well known method. The second substrate 51 may be an entire Si wafer or a divided wafer. The second substrate is needed to have the same shape as the first substrate.

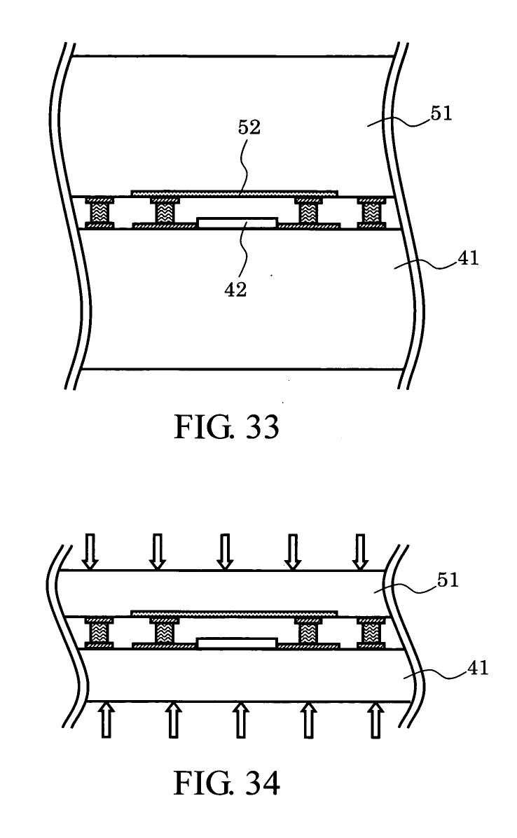

In FIG. 33, the first bumps 45 for internal connection and the second internal electrode pads 53 are connected by facing the surfaces of the first substrate 41 and the second substrate 51 by thermocompression. Simultaneously, the bumps 46 for sealing and the second pads 54 for sealing are junctioned and sealed.

In FIG. 34, the first substrate 41 and the second substrate 51 are thinned up to the thickness of 200 micrometers by grinding them on their backsides.

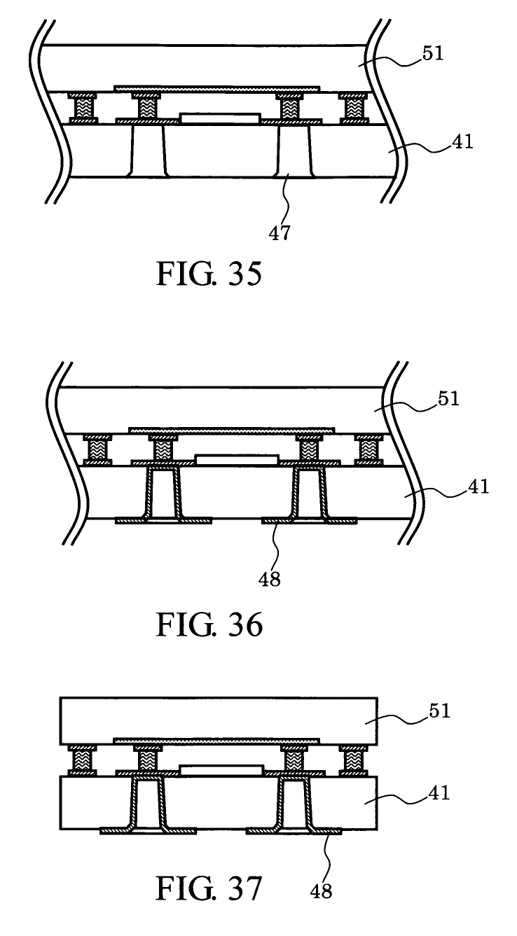

In FIG. 35, well 47 of 200 micrometers inner diameter and depth which extend to the back sides of the first internal electrode pads 43 from the first substrate 41 are formed using a well-known photolithographic process and reactive ion etching process. Then, as mentioned above about the first example, the chamfered edges S can be formed surely and easily. Further, the well 47 may be opened in a taper shape. In FIG. 36, Ti adhesion layer and Au electrode layer are deposited conformally in the walls and at the bottom of the well 47 and on the backside of the second substrate 41 by a sputtering, for example. And the external electrode pads 48 are patterned by lithography and dry etching. By this process, the first internal electrode pads 43 and the external electrode pads 48 can be connected electrically. In FIG. 37, the perimeter of the bumps 46 for sealed are separated for every chip by dicing. The major steps of the wafer-level packaging is completed.

According to this example, without using resin, the package is sealed forming the cavity between the substrate 41 and the substrate 51 by the bumps of soft metal for sealing. Since resin is not used, the wafer-level package having high hermeticity and relativity, such as high heat resistance can be provided.

### SIXTH EMBODIMENT

Next, as the sixth example of the invention, the wafer-level package where the well is opened in the semiconductor substrate and external electrode pads are connected will be explained.

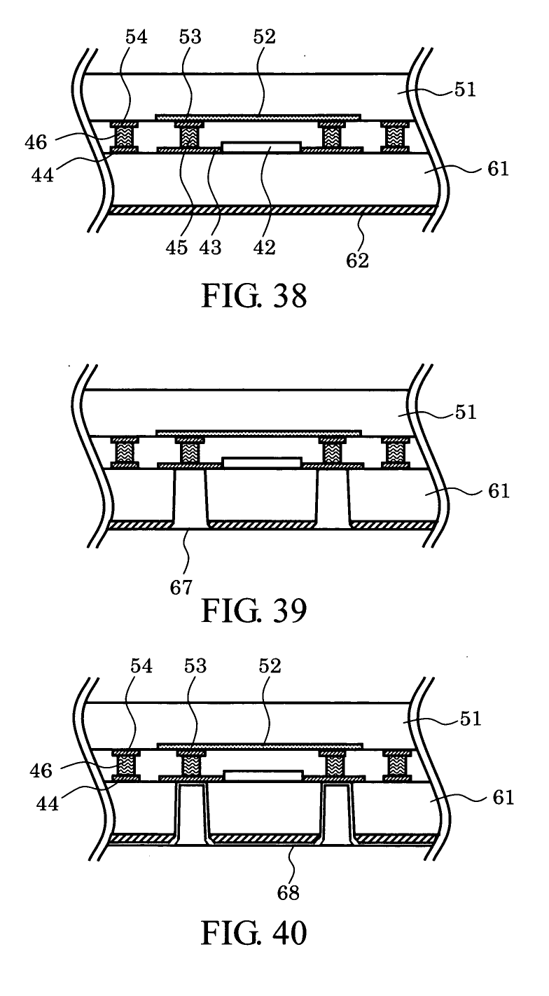

FIG. 38 through FIG. 42 show process steps for manufacturing method of the wafer-level package of this example. The same symbols are given to the same elements as what were mentioned above with references to FIG. 1 through FIG. 37 about this figure, and detailed explanation will be omitted.

First, FIG. 38 corresponds to FIG. 34 mentioned above about the fifth example. But, the non-insulation silicon substrate 61 is used instead of the insulating Si substrate 41. And the nitride silicon (SiNₓ) layer 62 is formed on the back side of the non-insulation silicon substrate 61.

In FIG. 39, well 67 of 200 micrometers inner diameter and depth which extend to the back sides of the first internal electrode pads 43 from the first substrate 61 are formed using a well-known photolithographic process and reactive ion etching process. Then, as mentioned above about the first example, the chamfered edges S can be formed certainly and easily. Further, the well 47 may be opened in a taper fashion.

In FIG. 40, the inner walls of the well 67 are covered with the silicon-oxide (SiOₓ) film 68 by forming the silicon-oxide (SiOₓ) film on the backside of the substrate 61.

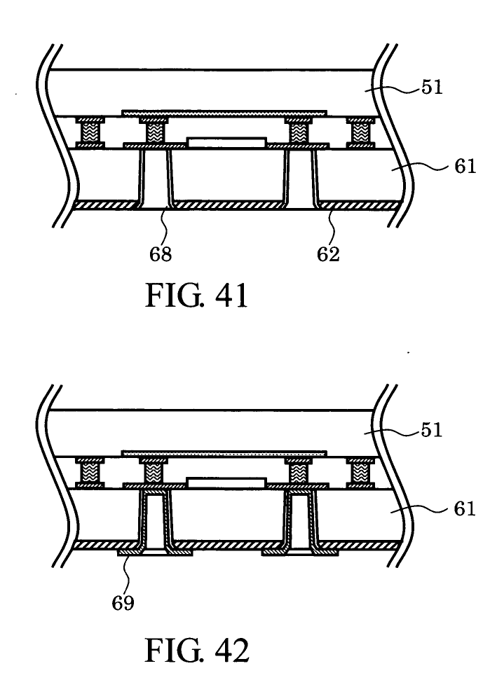

In FIG. 41, the silicon-oxide film 68 formed on the back of the substrate 61 and at the bottom of the well 67 is removed by etching. In this process, the anisotropic etching method, such as RIE (reactive ion etching) can be used.

In FIG. 42, Ti adhesion layer and electrode layer of gold are formed conformaly as a film at the bottom and on the side of the well 67 by the sputtering method. The external electrode pads 69 are patterned by lithography and dry etching. Simultaneously, the first inside electrode 43 and external electrode pads 69 can be connected electrically.

Then, as mentioned above about FIG. 37, the perimeter of the bumps 46 for sealed is separated for every chips by dicing. And the major steps of the wafer level package are completed.

According to this example, it becomes possible to form via plug structure in the non-insulation silicon substrate 61 by providing appropriately insulating films, such as the nitride silicon film 62 and the silicon-oxide film 68.

Heretofore, the embodiments of the present invention have been explained, referring to the examples. However, the present invention is not limited to these specific examples. For example, conductivity, insulation, or half-conductivity is sufficient as a pair of substrates which are arranged in a facing fashion each other and form a cavity among them. Accordingly, it is intended to embrace all such variations, which fall within the scope of the present invention. Moreover, an element provided between pairs of the substrates can include electric element, such as a transistor, a diode, a resistive element, a capacitor, an inductor, an oscillation element, and a relay, and machine element and optical element, such as a micro actuator and a polygon mirror.

Further, about the number and arrangement of the electric element contained in the wafer-level package and of well provided on the substrates may be appropriately selected by those skilled in the art with the known techniques to carry out the invention as taught in the specification and obtain equivalent effects.

Further, also concerning the wafer-level package according to the invention, those skilled in the art will be able to carry out the invention appropriately selecting a material or a structure within known techniques.

1. A wafer-level package comprising:
a first substrate;
an electric element provided on the first substrate;
a second substrate opposed to the first substrate with a predetermined gap therebetween, the electric element being provided between the first and second substrates;
an internal electrode pad extending onto a first surface of one or both of the first and the second substrates, the internal electrode pad being connected to the electric element;
a well penetrating the one of the first and the second substrates to the internal electrode; and
an external electrode pad provided on a second surface of the one of the first and the second substrates, the external electrode pad extending onto an inner wall of the well and being connected with the internal electrode pad.

2. The wafer-level package according to claim 1, wherein the well is tapered so that an inner diameter thereof becomes smaller toward the internal electrode pad.

3. The wafer-level package according to claim 1, wherein the well has an first opening end provided remoter from the internal electrode pad, and a second opening end provided closer to the internal electrode pad, and a chamfered edge is formed at the first opening end.

4. The wafer-level package according to claim 1, wherein the thickness of the external electrode pad on the inner wall of the well is less than a half of an inner diameter of the well, and a hole surrounded by the external electrode pad on the inner wall has an opening on the second surface of the substrate.

5. The wafer-level package according to claim 1, wherein the one of the first and the second substrates is the second substrate, and the electric element and the internal electrode pad is connected by a metallic bump.

6. The wafer-level package according to claim 1, wherein the one of the first and the second substrates is the second substrate, and the electric element and the internal electrode pad is connected by a conductive resin.

7. The wafer-level package according to claim 1, wherein the first substrate and the second substrate are bonded by an adhesive resin.

8. The wafer-level package according to claim 1, wherein the first substrate and the second substrate are bonded by a metallic bump.

9. A method for manufacturing a wafer-level package comprising:
forming an electric element and an internal electrode pad connected to the electric element on a first surface of a first substrate;
bonding a second substrate to the first substrate by a bonding member so that the electric element and the internal electrode pad are placed between the first and second substrates;
forming a well extending from a second surface of the first substrate to the internal electrode pad;
forming an external electrode pad extending from the second surface of the first substrate to the internal electrode pad through an inner wall of the well.

10. The method for manufacturing a wafer-level package according to claim 9, wherein the first substrate is thinned by grinding on the second surface before forming the well.

11. The method for manufacturing a wafer-level package according to claim 9, wherein the well has an first opening end provided on the second surface of the first substrate and a second opening end provided on an inner surface of the first substrate, and a chamfered edge is formed at the first opening end.

12. The method for manufacturing a wafer-level package according to claim 9, wherein the well is tapered so that an inner diameter thereof becomes smaller toward the internal electrode pad.

13. The method for manufacturing a wafer-level package according to claim 9, further comprising:
providing an adhesive resin so as to surround the electric element and the internal electrode pad on at least one of the first and the second substrates; and
dicing the first and the second substrates at a portion where the first and the second substrates are bonded by the adhesive resin.

14. The method for manufacturing a wafer-level package according to claim 9, further comprising:
providing a sealing pad so as to surround the electric element and the internal electrode pad on at least one of the first and the second substrates; and
dicing the first and the second substrates at an outside of a portion sealed by the sealing pad.

15. A method for manufacturing a wafer-level package comprising:
forming an electrical element on a first surface of a first substrate;
forming an internal electrode pad on a first surface of a second substrate;
arranging the first and the second substrates face to face so that the electric element on the first substrate is connected to the internal electrode on the second substrate by a bump;
forming a well extending from a second surface of the second substrate to the internal electrode pad; and
forming an external electrode pad extending from the second surface of the second substrate to the internal electrode pad through an inner wall of the well.

16. The method for manufacturing a wafer-level package according to claim 15, wherein the second substrate is thinned by grinding on the second surface before forming the well.

17. The method for manufacturing a wafer-level package according to claim 15, wherein the well has an first opening end provided on the second surface of the second substrate and a second opening end provided on the first surface of the second substrate, and a chamfered edge is formed at the first opening end.

18. The method for manufacturing a wafer-level package according to claim 15, wherein the well is tapered so that an inner diameter thereof becomes smaller toward the internal electrode pad.

19. The method for manufacturing a wafer-level package according to claim 15, further comprising:
providing an adhesive resin so as to surround the electric element and the internal electrode pad on at least one of the first and the second substrates; and
dicing the first and the second substrates at a portion where the first and the second substrates are bonded by the adhesive resin.

20. The method for manufacturing a wafer-level package according to claim 15, further comprising:
providing a sealing pad so as to surround the electric element and the internal electrode pad on at least one of the first and the second substrates; and
dicing the first and the second substrates at an outside of a portion sealed by the sealing pad.
